(19) United States
(12) Patent Application Publication
(10) Pub. No.: US 2023/0251296 A1
(43) Pub. Date: Aug. 10, 2023

(54) SYSTEMS AND METHOD FOR THE DESIGN AND RELIABILITY EVALUATION OF THE SURFACE SUBCOMPONENT OF INSULATION SYSTEMS

(71) Applicant: THE FLORIDA STATE UNIVERSITY RESEARCH FOUNDATION, INC., Tallahassee, FL (US)

(72) Inventors: Michael Steurer, Tallahassee, FL (US); Gian Carlo Montanari, Tallahassee, FL (US); Christoph Diendorfer, Tallahassee, FL (US); Qichen Yang, Tallahassee, FL (US)

(21) Appl. No.: 18/158,816

(22) Filed: Jan. 24, 2023

Related U.S. Application Data
(60) Provisional application No. 63/267,576, filed on Feb. 4, 2022.

(51) Int. Cl. G01R 31/12; G06F 1/18

(52) U.S. Cl. CPC G01R 31/1263; G06F 1/188

(57) ABSTRACT

Systems and methods are provided for producing optimized electronic components. Particularly, the systems and methods may involve the use of a “three-legged approach” for determining design parameters for electrical components (and/or insulation of the electrical components) such that the electrical component is not subject to partial discharges (PDs) at a maximum operating voltage of the electrical component. The approach may involve extracting maximum bulk (e.g., orthogonal) and surface (e.g., tangential) electrical stress (e.g., electrical field) information at operating temperatures, comparing the values of these electric fields with electric field values that are likely to cause the inception of one or more PDs in the electrical component (which may be determined through modeling), and linking these results with PD measurements (such as the surface partial discharge inception voltage, SPDIV).

### CROSS-REFERENCE TO RELATED APPLICATIONS

This application claims priority to and benefit of U.S. provisional patent application No. 63/267,576, filed Feb. 4, 2022, which is herein incorporated by reference.

### BACKGROUND

Moving towards maximizing power density and dynamics, the supply of electrical components in industrial, electrified transportation, and renewable electrical assets (as well as other electrical components used in various other contexts) are shifting from using sinusoidal alternating current (AC) to modulated AC and direct current (DC), which are associated with voltage and load transients. The voltages being used with such components are also increasing to the megavolt (MV) range, which results the components needing to be designed to withstand, for the specified operational lifespan of the components, high electric fields and temperatures. Furthermore, fast switching times and high modulation and carrier frequencies of power electronics may also need to be managed. This results in electrical, thermal, and mechanical stress profiles which can change significantly with supply voltage and time. These stress profiles may impact (e.g., increase) electrothermal and mechanical aging rates of the components based on both intrinsic and extrinsic aging factors. As an example, the electric field in bulk insulation defects or on the printed circuit board (PCB) surface may incept partial discharges (PDs) (for example, a localized electrical discharge that only partially bridges the insulation between conductors and which may or may not occur adjacent to a conductor) for some stress conditions, with different PD amplitude and repetition rates for AC and DC components. This may impact the extrinsic aging rate, so that life reduction of the components may be dramatic even if PD activity is discontinuous.

Reliability and safety issues must be faced when designing and maintaining insulation of these components, which are designed under the constraints of maximizing the specific power and, therefore, reducing dimensions. This can be related to electric field and temperature magnitude and profile, as well as on the increased likelihood of inception of surface partial discharge (PD). Surface properties in insulation subsystems, such as in printed circuit boards (PCBs), laminated busbars (LBBs), spacer and bushings, may be largely affected by such issues, and, therefore, contribute to worsening the long-term reliability of these components.

### BRIEF SUMMARY

A method is provided. In one aspect, the method includes: (i) determining, using one or more processors, one or more first electrical fields associated with operation of an electrical component; (ii) comparing, using the one or more processors, the one or more first electrical fields with a second electrical field associated with partial discharge (PD) inception in the electrical component; (iii) determining, using the one or more processors, that a first value associated with the one or more first electric field value is less than or equal to a second value associated with the second electric field; and (iv) generating, using the one or more processors and based on the determination that the first value is less than or equal to the second value, parameters for insulation of the electrical component.

In another aspect, a system is provided that includes one or more processors and a memory storing computer-executable instructions, that when executed by the one or more processors, cause the one or more processors to: (i) determine one or more first electrical fields associated with operation of an electrical component; (ii) compare the one or more first electrical fields with a second electrical field associated with partial discharge (PD) inception in the electrical component; (iii) determine that a first value associated with the one or more first electric field value is less than or equal to a second value associated with the second electric field; and (iv) generate, based on the determination that the first value is less than or equal to the second value, parameters for insulation of the electrical component.

In still another aspect, a non-transitory computer readable medium is provided that includes computer-executable instructions stored thereon, which when executed by one or more processors, cause the one or more processors to perform operations of: (i) determining, using one or more processors, one or more first electrical fields associated with operation of an electrical component; (ii) comparing, using the one or more processors, the one or more first electrical fields with a second electrical field associated with partial discharge (PD) inception in the electrical component; (iii) determining, using the one or more processors, that a first value associated with the one or more first electric field value is less than or equal to a second value associated with the second electric field; and (iv) generating, using the one or more processors and based on the determination that the first value is less than or equal to the second value, parameters for insulation of the electrical component.

### BRIEF DESCRIPTION OF THE DRAWINGS

The detailed description is set forth with reference to the accompanying drawings. The use of the same reference numerals indicates similar or identical components or elements; however, different reference numerals may be used as well to indicate components or elements which may be similar or identical. Various embodiments of the disclosure may utilize elements and/or components other than those illustrated in the drawings, and some elements and/or components may not be present in various embodiments. Depending on the context, singular terminology used to describe an element or a component may encompass a plural number of such elements or components and vice versa.

FIG. 1 is an example plot, in accordance with one or more embodiments of the disclosure.

FIG. 2 is an example plot, in accordance with one or more embodiments of the disclosure.

FIG. 3 is a plan view of an example layout of an example PCB, in accordance with one or more embodiments of the disclosure.

FIG. 4 is a plan view of an example of close contacts fed by AC voltage, in accordance with one or more embodiments of this disclosure.

FIGS. 5A-5B are example plots, in accordance with one or more embodiments of this disclosure.

FIGS. 6A-6B are example plots, in accordance with one or more embodiments of this disclosure.

FIG. 7 is an example plot, in accordance with one or more embodiments of this disclosure.

FIG. 8 is an example plot, in accordance with one or more embodiments of this disclosure.

FIG. 9 is an example plot, in accordance with one or more embodiments of this disclosure.

FIG. 10 illustrates an example system, in accordance with one or more embodiments of the disclosure.

FIG. 11 is a block flow diagram illustrating a method in accordance with one or more embodiments of this disclosure.

FIG. 12 illustrates an example of a computing device, in accordance with one or more embodiments of this disclosure.

### DETAILED DESCRIPTION

Systems and methods are provided for producing optimized electrical components. For example, the systems and methods described herein may provide optimized designs of a surface of the insulation of electrical components, such as spacers, bushings, cable accessories, power electronics boards, PCBs, laminated busbars (LBB), and/or any other types of electrical components that may include an insulating material. These systems and methods may not necessarily be limited to the surface of the insulation of such components, but may also be applicable to any other portion of the insulation (such as the “bulk” of the insulation, for example), as well as any other portion of the electrical components other than the insulation. Thus, any reference individually herein to “insulation,” “component,” “electrical component,” and the like is not intended to be limiting.

Particularly, the systems and methods described herein may optimize parameters of electrical components, such as reliability, lifespan, dimensions, weight, distance between electrodes, distance between electrodes and ground, the shape of electrodes and/or connectors, and/or any other parameters, while mitigating the risk of producing extrinsic aging phenomena (which may reduce the lifespan of a component). In some instances, this optimization may involve determining modified parameters for an existing electrical component. In other instances, the optimization may involve determining parameters that may be used to create a new electrical component. For example, once the optimized parameters for an electrical component are determined, a computer-based instruction may be sent to a device or system that is used to manufacture or modify the electrical component. The instruction, for example, may include an indication of the parameters, such that the electrical component that is produced is based on the optimized parameters (for example, the instruction may be associated a computer-aided design and/or any other type of format that may be used to create or modify the electrical component). The device or system may then create the electrical component based on the instruction. If the methods are applied to an existing component, the device or system may be used to modify the component to match the updated parameters. Similarly, the optimized parameters may be used to create insulation and/or components of the insulation for the electrical component as well.

The method used to generate these optimized parameters is referred to as a “three-legged approach” herein and may be based on comparisons of results derived from electric stress profile simulation (e.g., electric field simulation), PD modeling, and PD measurements using a type of waveform that may be associated with the electrical component. For example, the waveform may be a sinusoidal AC waveform, modulated AC or DC waveform, and/or any other type of waveform. In one or more embodiments, the method may specifically involve extracting (by calculations or simulations, for example) electric field profiles associated with the surface and/or bulk of the insulation at operating temperatures, comparing the values of these electric fields with electric field values that are likely to cause the inception of one or more PDs in the electrical component (which may be determined through modeling), and linking these results with PD measurements (such as the surface partial discharge inception voltage, SPDIV, which may be a voltage threshold beyond which a PD may occur, for example). In some cases, the electric fields may include orthogonal and tangential electric fields, however, any other types of electric fields may also be used. The result of this approach is an electrical component design (and/or insulation design for the electrical component) that is not subject to PDs within a maximum operating range of the electrical component.

Conventional approaches often involve basing insulation design on creepage and clearance values (creepage may be the shortest distance between two conducting points along the surface of an insulating material, while clearance may be the shortest distance in the air between two conducting parts), which is related to macroscopic destructive events. Extrinsic, accelerated insulation aging may already initiate if and when PD is incepted. Inception of PD may cause premature failure, even if not immediate. In contrast, the method describes herein ensures that the PDIV (e.g., for surface and bulk insulation sub-components) is not exceeded under any operating condition and for any level of surface contamination. The distances between electrodes and ground connection, and, when possible, the shape of electrodes and/or connectors (as well as any other parameters), may be selected in such a way that the operating voltage of the component is lower than PDIV and SPDIV). This may be measured using an appropriate detector that distinguishes between internal, surface, and corona discharges (for example, partial discharges generated by internal, bulk defects, on insulation surface and in air, respectively). The creepage criterion may be kept to establish the limit length of the surface to avoid macroscopic discharges, but feasibility may still be based on no surface PD at any operating condition. That is, regardless of the creepage value, if the operating voltage SPDIV is exceeded, the insulation system may not be reliable, thus may not be may not be capable of working under operation. This method provides design criteria that focus on simulation, modeling, and measurements that are also applicable to high voltage components (for example, components that involve voltages in the mega volt (MV) or greater range (or any other similar type of high voltage).

This approach links electric field and temperature profile simulations to component lifespan and/or discharge modeling and PD measurements, so that the electrical field of the designed insulation can be associated with component lifespan and the likelihood of PD inception. The inception of surface PD may cause premature insulation breakdown, even if in unpredictable times, resulting in reduced reliability and lifespan of the component. In one or more embodiments, the focus may be on AC field simulation and modeling, and may also include automatic, unsupervised PD measurements. However, this approach can be extended to DC voltage supply and power electronics waveforms, as well as any other use case.

In one or more embodiments, the AC and/or DC electric field simulation may be performed for the surface of a test object (for example, spacers, bushings, cable accessories, power electronics boards, PCBs, laminated busbars (LBB), and/or any other types of objects), which may be physical hardware that is tested using the simulation described herein. The simulations may also factor other stresses (such as thermal stresses, for example). In the case of DC voltages, the presence of a surface layer with conductance properties different from the insulation bulk may be used. Field simulation may be performed at the maximum operating voltage of the component, considering the possible presence of repetitive or sporadic voltage transients and contamination (e.g., worst-case conditions). The field for surface PD inception, Eᵢ, may be estimated by an appropriate model. An example is given by:

$${E}_{i} = {( \frac{E}{p} )}_{cr} \cdot p ( 1 + \frac{B}{{( {pk}_{s} l )}^{\frac{1}{{β}_{is}}}} ) \qquad ( Equation 1 )$$

$$with$$

$$\begin{matrix}B = \frac{{( \frac{{K}_{cr}}{C} )}^{\frac{1}{{β}_{is}}}}{{( \frac{E}{p} )}_{cr}} & ( Equation 2 )\end{matrix}$$

where (E/p)_{cr}, C, K_{cr}, and βᵢₛ are parameters related to the physics of the ionization process, l may be the distance from the positive electrode to negative electrode and kₛ may be a factor taking into account the field gradient (under the assumption that since model (1) with kₛ=1 holds for uniform field along l, while in the presence of field gradient an equivalent distance must be defined where most of the field variation is involved in electron avalanche generation). Parameter k, which accounts for the extent of field gradient at the interface between electrode and/or contact and insulation surface, may be expressed for example as

kₛ=(l(0.95E_{M})⁺−l(0.95E_{M})⁻)/l (Equation 3)

where EM⁺,EM⁻ are maximum electric field values and are derived through field simulation of specific test object (superscripts “+” and “−” indicate the field profile curve derivative).

If the maximum surface (e.g., tangential) field provided by the simulations exceeds the PD inception field (for example, determined by Equation 1) the risk of PD inception may be high. Based on this comparison, the design parameters of the insulation may be modified until the maximum surface field is equal to or less than the PD inception field. This may be verified by performing PD measurements using a smart type of detector which is able to identify automatically surface PD and reject noise. While reference is made specifically to comparing the maximum surface field and the PD inception field, this is not intended to be limiting, and comparisons may be made between any other type of electric fields as well.

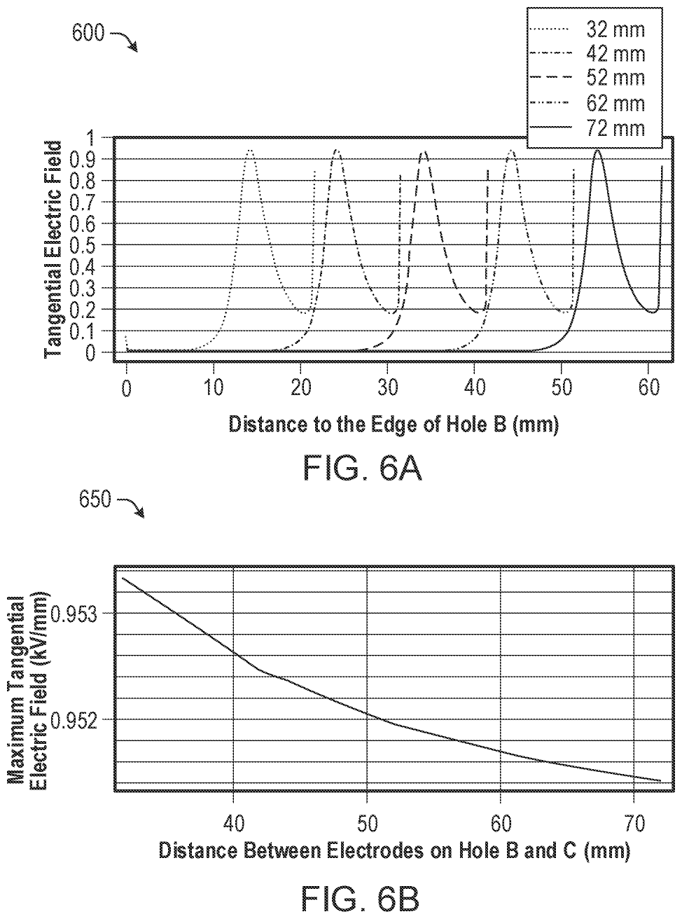

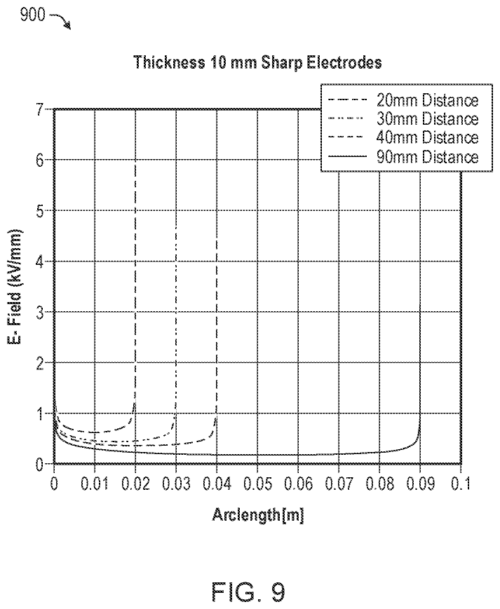

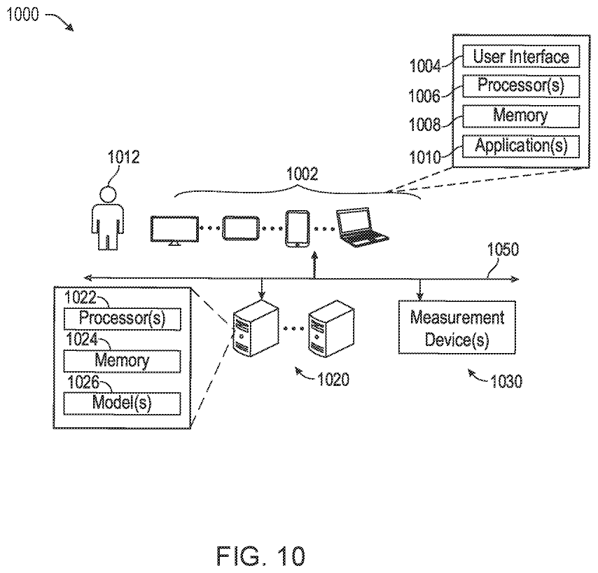

The benefits of this approach are illustrated by FIGS. 6A-6B, which shows plots 600 and 650 depicting results of electric field simulations carried out for an example PCB. As shown by the field profiles, the maximum field values may not necessarily change significantly with the distance between connectors and/or electrodes. This confirms simulations illustrated in FIG. 9, where electrodes with less sharp edges results in a decrease of the maximum field with creepage, but may be limited and unable to bring the maximum field below the values of surface discharge inception field, Eᵢ (which is in the range 1.5 to 2 (from Equation 1) for the various distances shown in FIG. 10). The results indicate that increasing creepage may prevent macroscopic discharges, but may not be able to guarantee that the maximum surface field falls below the SPDIV.

In one or more embodiments, any of the aspects of the “three-legged approach” as described herein may be performed using artificial intelligence, machine learning, or the like. For example, machine learning model may be used to produce the design parameters that may be used to create one or more electrical components and/or the insulation of the electrical components as outputs. In some cases, an output of the machine learning model may include an indication of design parameters that may be provided to may be provided as an instruction to a device or system to produce the electrical component and/or the insulation as aforementioned.

The machine learning model may also be initially trained using historical data and may also be trained in real-time such that the performance of the machine learning model is improved over time to produce more accurate design parameters. For example, the machine learning model may be trained with historical data relating to design parameters that were previously determined based on the three-legged approach described herein. subsequent to the machine learning model being trained using this historical data, when the machine learning model is used to output design parameters for an electrical component and/or insulation of the electrical component, a feedback loop may be used to determine the accuracy of the machine learning model output. For example, the system may simultaneously generate design parameters without using the machine learning model and these results may be compared to the output of the machine learning model. As another example, a user may manually indicate the accuracy of the output of the machine learning model. In some instances, the machine learning model may be self-trained iteratively in this manner until a threshold level of accuracy is achieved. However, in other instances, the machine learning model may continue to be improved using this feedback mechanism. While reference is made to machine learning, this is merely exemplary, and any other type of model may similarly be used.

In one or more embodiments, two basic problems associated with insulation system design may include: (1) satisfying the reliability (“R”) specifications (e.g., an estimated lifespan of a component for a given failure probability of the component) of the components and (2) avoiding defects and optimizing connector and surface insulation shape and size for both the AC and DC sub-components.

The first problem may be managed by the knowledge of component lifespan models and the availability of accelerated component lifespan tests (at different fields and temperatures) that allow the electric field of the component to be estimated for the specified lifespan and failure probability (“P”) of the component (for example, given by P=1−R).

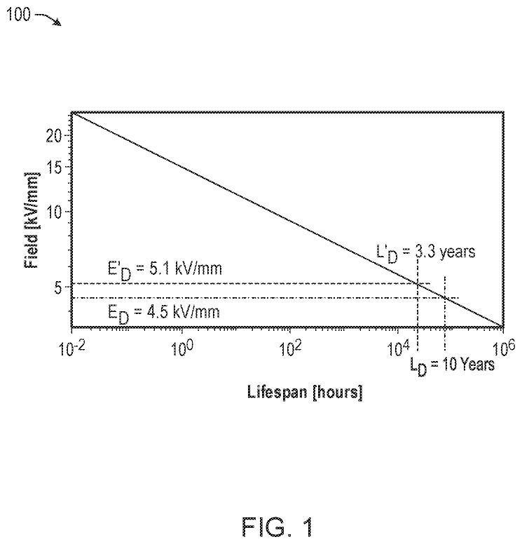

FIG. 1 illustrates an example plot 100 showing component lifespans (shown on the x-axis) plotted in a log-log coordinate system. From extrapolation of the regression line (the inverse power model is linear in log-log coordinates), the maximum electric field of a component (shown on the y-axis) may be estimated given a fixed lifespan and failure probability for the component. For example, a component with a lifespan of 10 years at a failure probability of 1% may correspond to an electric field of 4.5 kV/mm. This may drive the estimation of the insulation thickness (and/or any other parameters), considering that the maximum electric field may not exceed the value provided by the lifespan extrapolation. An increase of electric field of, for example, 10% with respect to the design value may cause a significant reduction of life (for example, from 10 to 3.3 years for the case of FIG. 1). This holds when the field is enhanced in the whole insulation thickness, however, even if the electric field is increased only locally, for example at the interface between the copper layer and insulating material, an aging rate may be strongly accelerated at that location, and may ultimately propagate through the entirety of the insulation volume. To address this, it may be assumed that the field in insulation bulk is always lower than the electric field established by lifespan. The last consideration is that lifespans and insulation system design may be referred to the real thickness, which makes the statistical approach to the size (dimensional) effect a fundamental tool.

The second problem pertains to the likelihood of surface and/or interface discharges. While compliance with the first problem may ensure an appropriate insulation thickness, the impact of extrinsic aging mechanisms on insulation bulk and surface and/or interfaces may be determined through PD modeling. The presence of extrinsic aging mechanisms, such as PD or space charge accumulation, may cause much faster aging and premature failure of the component. This may occur if there are defects in the bulk that may incept internal PD (and accumulation of space charge in the DC PCB sub-component), but may also occur if PD is present at the insulation surface and/or interfaces. Accurate evaluation of creepage and clearance, which may be related to the risk of macroscopic discharges, may not be sufficient to ensure the design life and failure probability. The presence of surface PD, especially at the interface between electrodes and/or connectors and insulation, may cause accelerated local degradation processes to be activated by surface PD inception. Even small surface PD activity may cause extrinsic aging, and thus may affect the reliability of the whole insulation.

Using an initial structural design for the insulation (and/or the electrical component), electric fields may be calculated and/or simulated for different operating temperatures and relevant temperature gradients for internal defects and at the surface and/or interfaces (e.g., the “first leg” of the “three-legged approach”). The PD inception field may be estimated through the models developed according to the “second leg” of the “three-legged approach.” This PD inception field may be compared to the electric fields determined through the “first leg.” Finally, the estimated inception field may then be compared to a measured quantity (e.g., PD inception voltage). Thus, the “third leg” may involve PD measurements under AC and DC, which relates the field distribution and inception field calculation to the likelihood to experience PD under operation. The ultimate goal may be a design that results in no PD for any operating conditions of the component, with particular attention to temperature and field gradients for the DC sub-component of the insulation system (under DC, the electric field, depending on conductivity, may be strongly altered and locally amplified by temperature and field gradients). It should be noted that any reference specifically to insulation may also be applicable to any other portion of an electrical component. Additionally, in some cases, any reference to the surface of the insulation or bulk of the insulation is not intended to be limiting and may refer to any other portion of the insulation as well.

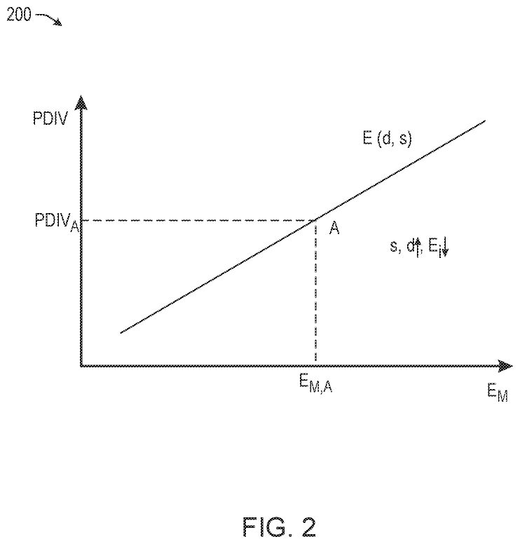

FIG. 2 illustrates a plot 200 that summarizes this “three-legged approach” approach applied to a PCB. As shown in the plot 200, the discharge inception field, Eᵢ, decreases with increasing defect size, d, or surface span, s (for example, distance from the electrode to ground). “A” is the upper design limit, defining a reliable design with nominal voltage, Vn, <PDIV_{A}, design field, E_{D}>E_{M} (e.g., maximum field), d<d₁, and s>s₁. This holds for nearly-uniform surface fields, for example. In some instances, in the presence of a significant field gradient, the maximum field near the electrode and the insulation surface span may not be correlated in terms of the risk of incepting PD. Electric field simulations may be performed to estimate the electric field of the PCB busbar (or any other component) with peripheral components under different electrical stresses to observe the impacts of geometry and material characteristics on the electric field distribution.

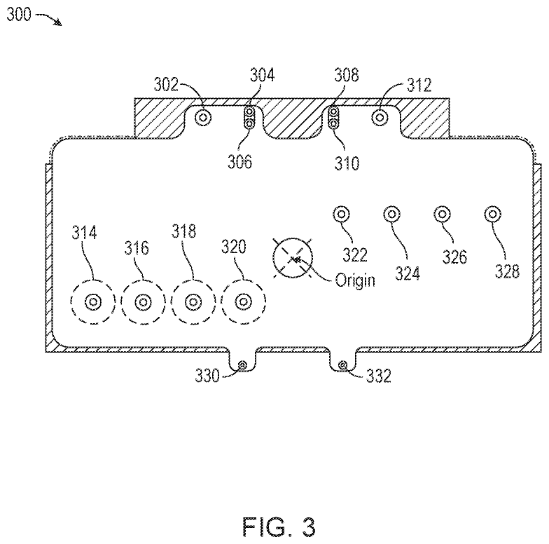

FIG. 3 shows an example of the layout of a PCB 300 (for example, a specific type of electrical component). In this example, the PCB 300 may include a nominal voltage 5 kV (however, this is not intended to be limiting). Both insulation layer thickness and surface distance (span) between varying contacts (for example, contacts 302-332) provided on the PCB 300 may need to be optimized for size and reliability (e.g., specified lifespan and the likelihood of PD inception). Although FIG. 3 shows a PCB 300, this is merely an exemplary electrical component.

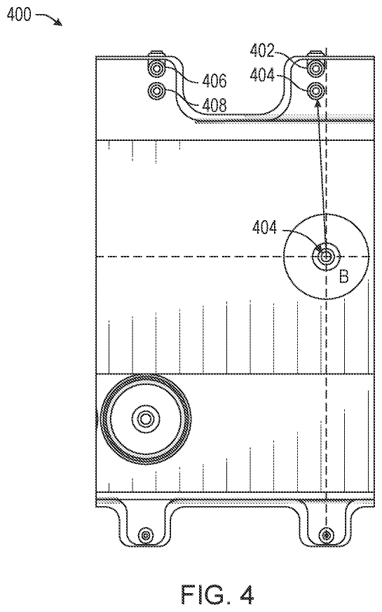

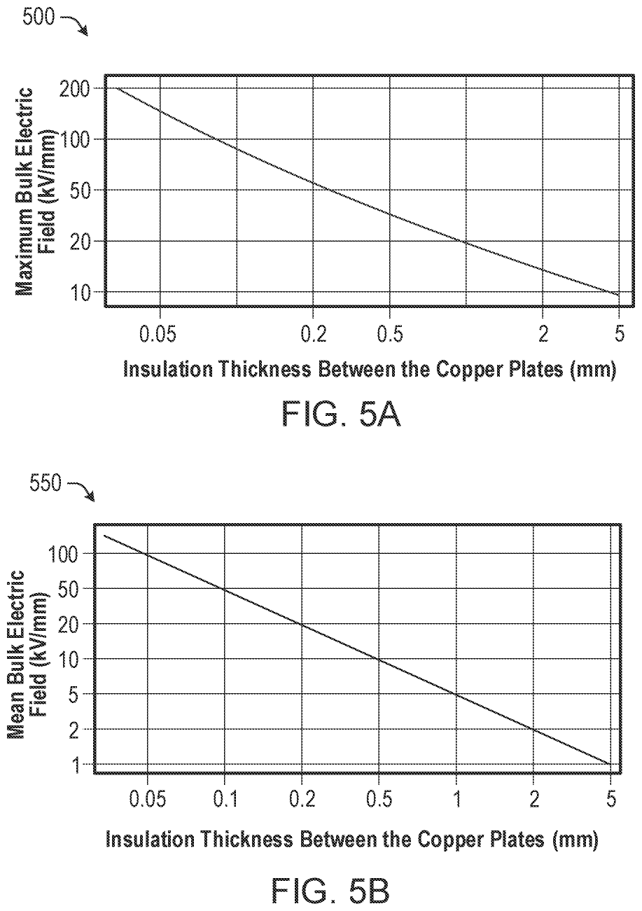

FIG. 4 displays a section of the example AC sub-component 400 in which the contacts are closer (e.g., among those involving the surface of the insulation, such as contacts 402-408) and, consequentially, the surface field is higher. The surface PDIV (SPDIV) must be high enough to allow the PCB to operate without PD at nominal voltage. FIGS. 5A-5B report results of simulation of the maximum orthogonal bulk field, which may be linked to insulation thickness choice and to the likelihood of PD inception in defects and/or internal interfaces where air and/or gas layers can be present. FIGS. 6A-6B show the profile of the surface tangential field (that ruling surface discharges) corresponding to contacts shown in FIG. 4.

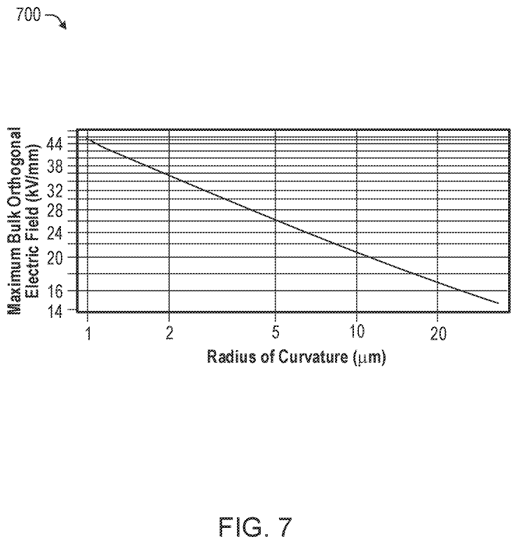

The electric field profiles in FIGS. 5A-5B and 6A-6B may be obtained considering a curvature radius of the conductor layer edges of 30 μm. FIG. 7 shows that the field gradient may depend on this curvature radius. As shown in FIG. 7, when the curvature radius changes from 30 μm to 0.5 μm, the field rises from 5 kV/mm to 400 kV/mm. It should be noted that any of the values referred with respect to FIGS. 4-6 (as well as any other figures described herein) are merely exemplary and not intended to be limiting.

Additionally, FIGS. 6A-6B indicate that increasing the distance between the contacts may significantly alter the maximum surface field (and thus the field gradient at the contact and/or insulation interface), so that surface PD inception field may be large enough to incept PD even if the creepage is increased. Hence, the calculation of the interface field may be important to estimate the surface partial discharge inception likelihood (and voltage). In some cases, increasing creepage may avoid macroscopic surface discharge between electrode and ground, but may not significantly influence the likelihood of surface PD inception.

FIGS. 6A-6B also show that the maximum surface tangential field may vary with the distance between the contacts (which may be physically closer in the AC sub-component). In some instances, the amount by which the surface tangential field varies may be limited due to the large field gradient at the connector and/or insulation interface. Considering a threshold value for the surface PD inception field, for such a field gradient, of, e.g., 1.2 kV/mm, the example nominal voltage of 5 kV may not incur in a significant risk of PD, with the maximum field being in the range of 0.9 to 1.0 kV/mm. This value may account also for the possibility of surface degradation due to extrinsic electrothermal and environmental aging, as well as contamination. Contamination and surface aging may also impact the value of Eᵢ that may be determined using the “second-leg” model, and thus the values of E_{M} and PDIV.

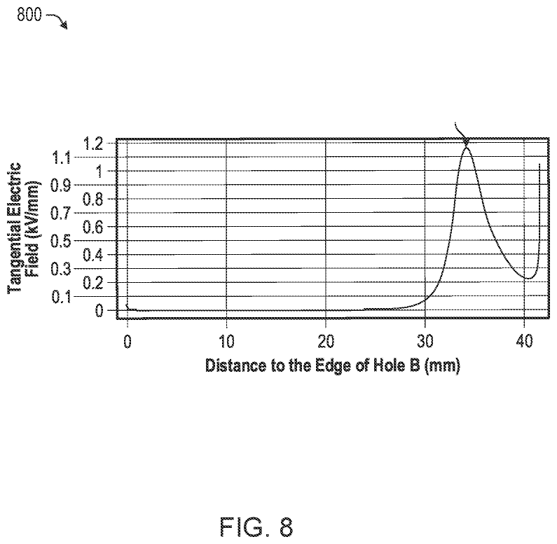

As a confirmation, preliminary AC PD measurements (e.g., the third leg) may indicate an inception voltage PDIV=6.1 kV, which is 20% above the nominal voltage. When performing simulations at this voltage level, the maximum surface tangential field increases to 1.16 kV/mm, as shown in FIG. 8, which is close to 1.2 kV/mm and thus supporting the surface discharge model (Equation 1). While performing the PD measurements of the third leg, noise is recognized and separated from PD. Increasing voltage above PDIV, the likelihood tends to increase, as discharges begin to expand on the surface between the contacts.

Regarding internal PD, calculations may show the height of an internal cavity above which the value of discharge inception, Eᵢ, may be exceeded. An approximate expression for the PD inception field, taken from Equation 1 may be:

$${E}_{i} = 25.2 p ( 1 + \frac{8.6}{\sqrt{ph}} )$$

where p may be the gas pressure inside the cavity and h may be the cavity height. Based on this calculation it may be determine that cavities of height larger than 75 μm may incept PD, (for example, the value of Eᵢ may be reached by the design mean (bulk) orthogonal field (2.5 kV/mm, see FIG. 5) and field ratio f being:

E_{c}=f Eₘ

where Eᵢ may be the field in the cavity, Eₘ that in the insulation and f≈εₘ/ε_{c}=4.24, that is, the ratio of permittivity of the insulation material and the gas in the cavity. Hence, mean design field lower than 2.5 kV/mm may be used for bulk insulation.

FIG. 9 illustrates an example plot 900, in accordance with one or more embodiments of this disclosure. The plot 900 shows an electric field simulation on the surface of a resin board, with two cylindrical electrodes, as a function of the distance between electrodes.

FIG. 10 is a schematic block diagram of an illustrative system 1000 in accordance with one or more example embodiments of the disclosure. In one or more embodiments, the system may include one or more user devices 1002 (which may be associated with one or more users 1012), one or more computing devices 1020, and/or one or more measurement devices 1030. However, these components of the system 1000 are merely exemplary and are not intended to be limiting in any way. For simplicity, reference may be made hereinafter to a “user device 1002,” “computing device 1020,” and “measurement device 1030,” however, this is not intended to be limiting and may still refer to any number of such elements.

The user device 1002 may be any type of device, such as a smartphone, desktop computer, laptop computer, tablet, and/or any other type of device. The device 1002 may include an application 1010 that may allow a user 1012 (a user 1012 may be an associate as described herein) to perform certain functions described herein, such as viewing results of any of the three legs of the “three-legged approach,” viewing final design parameters for insulation and/or an electrical component, etc. The user 1012 may also be able to use the application 1010 to perform other functionality, such as indicating that insulation and/or the electrical component should be created based on the design parameters and/or any other functionality. The user 1012 may be able to interact with the application 1010 through a user interface 1004 of the user device 1002. The user device 1002 may also include processor(s) 1006 and memory 1008.

The computing device 1020 may be any type of device or system used to perform any of the processing described herein For example, the computing device 1020 may be used to perform any of the simulations, modeling, measurements, etc. described herein. The computing device 1020 may also include one or more processors 1022 and memory 1024. Any of this processing may also be performed by the user device 1002 and/or any other device or system described herein as well.

The measurement device 1030 may be any type of device that is used to obtain measurements from an electrical component, test object, etc. For example, an oscilloscope may be used to obtain voltage and/or current measurements from an existing PCB to determine PD measurements. However, this is merely one example, and any other type of device that may be used to measure any other types of data may also be provided as well.

In one or more embodiments, any of the elements of the system 1000 (for example, one or more user devices 1002, one or more computing devices 1020, one or more measurement devices 1030, and/or any other element described with respect to FIG. 10 or otherwise) may be configured to communicate via a communications network 1050. The communications network 1050 may include, but not limited to, any one of a combination of different types of suitable communications networks such as, for example, broadcasting networks, cable networks, public networks (e.g., the Internet), private networks, wireless networks, cellular networks, or any other suitable private and/or public networks. Further, the communications network 1050 may have any suitable communication range associated therewith and may include, for example, global networks (e.g., the Internet), metropolitan area networks (MANs), wide area networks (WANs), local area networks (LANs), or personal area networks (PANs). In addition, communications network 1050 may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, white space communication mediums, ultra-high frequency communication mediums, satellite communication mediums, or any combination thereof.

Finally, any of the elements (for example, the user device 1002, computing device 1020, and/or measurement device 1030) of the system 1000 may include any of the elements of the computing device 1200 as well.

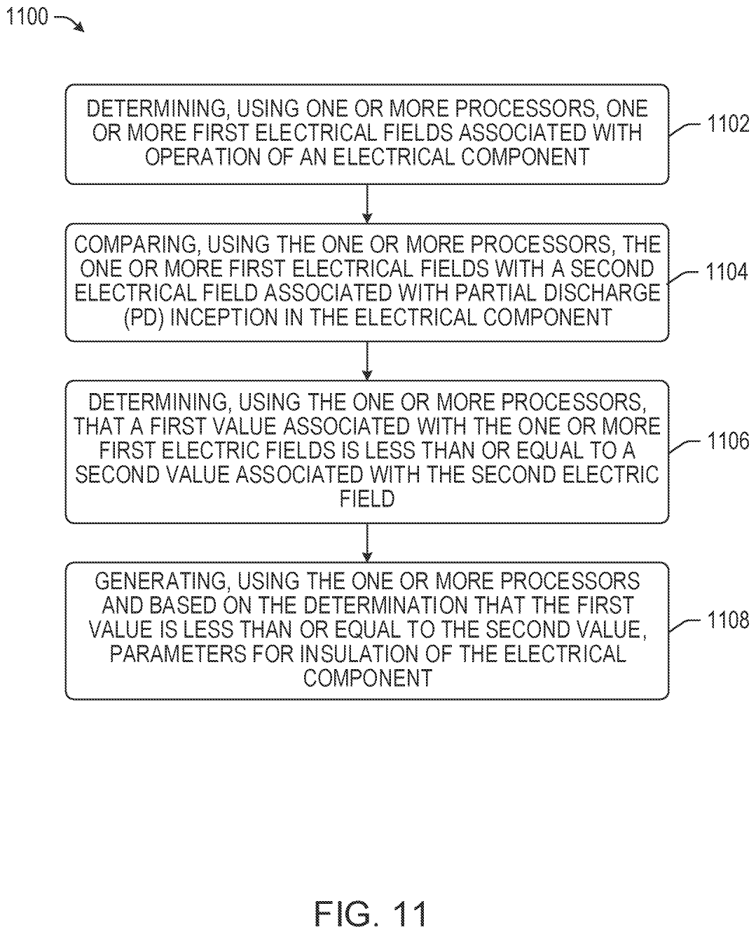

FIG. 11 depicts an example method 1100 in accordance with one or more example embodiments of the disclosure. Some or all of the blocks of the method 1100 in this disclosure may be performed in a distributed manner across any number of devices or systems (for example, user device 1002, computing device 1020, computing device 1200, and/or any other type of device, system, etc.). The operations of the method 1100 may be optional and may be performed in a different order.

At block 1102 of the method 1100, computer-executable instructions stored on the memory of a device may be executed to determine one or more first electrical fields associated with operation of an electrical component.

At block 1104 of the method 1100, computer-executable instructions stored on the memory of a device may be executed to compare the one or more first electrical fields with a second electrical field associated with partial discharge (PD) inception in the electrical component.

At block 1106 of the method 1100, computer-executable instructions stored on the memory of a device may be executed to determine that a first value associated with the one or more first electric fields is less than or equal to a second value associated with the second electric field.

At block 1108 of the method 1100, computer-executable instructions stored on the memory of a device may be executed to generate, based on the determination that the first value is less than or equal to the second value, parameters for insulation of the electrical component.

One or more operations of the methods, process flows, or use cases of FIGS. 1-11 may have been described above as being performed by a user device, or more specifically, by one or more program module(s), applications, or the like executing on a device. It should be appreciated, however, that any of the operations of the methods, process flows, or use cases of FIGS. 1-11 may be performed, at least in part, in a distributed manner by one or more other devices, or more specifically, by one or more program module(s), applications, or the like executing on such devices. In addition, it should be appreciated that the processing performed in response to the execution of computer-executable instructions provided as part of an application, program module, or the like may be interchangeably described herein as being performed by the application or the program module itself or by a device on which the application, program module, or the like is executing. While the operations of the methods, process flows, or use cases of FIGS. 1-11 may be described in the context of the illustrative devices, it should be appreciated that such operations may be implemented in connection with numerous other device configurations.

The operations described and depicted in the illustrative methods, process flows, and use cases of FIGS. 1-11 may be carried out or performed in any suitable order as desired in various example embodiments of the disclosure. Additionally, in certain example embodiments, at least a portion of the operations may be carried out in parallel. Furthermore, in certain example embodiments, less, more, or different operations than those depicted in FIGS. 1-11 may be performed.

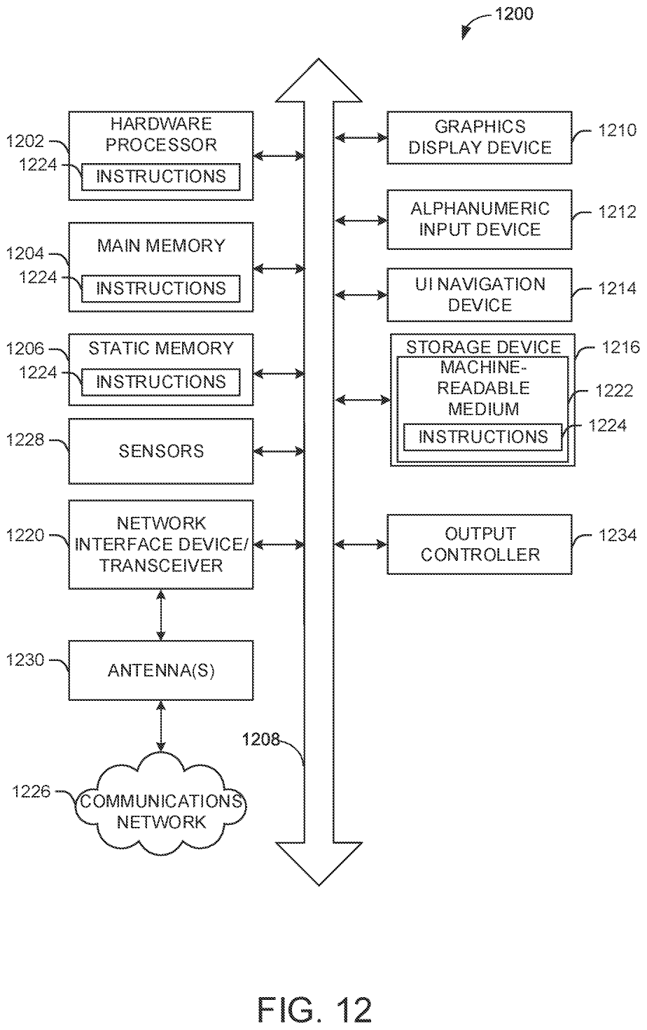

FIG. 12 depicts a block diagram of an example computing device 1200 upon which any of one or more techniques (e.g., methods) may be performed, in accordance with one or more example embodiments of the present disclosure. In other embodiments, the computing device 1200 may operate as a standalone device or may be connected (e.g., networked) to other machines. In a networked deployment, the computing device 1200 may operate in the capacity of a server machine, a client machine, or both in server-client network environments. In an example, the computing device 1200 may act as a peer machine in peer-to-peer (P2P) (or other distributed) network environments. The computing device 1200 may be a personal computer (PC), a tablet PC, a set-top box (STB), a personal digital assistant (PDA), a mobile telephone, a wearable computer device, a web appliance, a network router, a switch or bridge, or any machine capable of executing instructions (sequential or otherwise) that specify actions to be taken by that machine, such as a base station. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), or other computer cluster configurations.

Examples, as described herein, may include or may operate on logic or a number of components, modules, or mechanisms. Modules are tangible entities (e.g., hardware) capable of performing specified operations when operating. A module includes hardware. In an example, the hardware may be specifically configured to carry out a specific operation (e.g., hardwired). In another example, the hardware may include configurable execution units (e.g., transistors, circuits, etc.) and a computer readable medium containing instructions where the instructions configure the execution units to carry out a specific operation when in operation. The configuring may occur under the direction of the executions units or a loading mechanism. Accordingly, the execution units are communicatively coupled to the computer-readable medium when the device is operating. In this example, the execution units may be a member of more than one module. For example, under operation, the execution units may be configured by a first set of instructions to implement a first module at one point in time and reconfigured by a second set of instructions to implement a second module at a second point in time.

The computing device 1200 may include a hardware processor 1202 (e.g., a central processing unit (CPU), a graphics processing unit (GPU), a hardware processor core, or any combination thereof), a main memory 1204 and a static memory 1206, some or all of which may communicate with each other via an interlink (e.g., bus) 1208. The computing device 1200 may further include a graphics display device 1210, an alphanumeric input device 1212 (e.g., a keyboard), and a user interface (UI) navigation device 1214 (e.g., a mouse). In an example, the graphics display device 1210, alphanumeric input device 1212, and UI navigation device 1214 may be a touch screen display. The computing device 1200 may additionally include a storage device (i.e., drive unit) 1216, a network interface device/transceiver 1220 coupled to antenna(s) 1230, and one or more sensors 1228, such as a global positioning system (GPS) sensor, a compass, an accelerometer, or other sensor. The computing device 1200 may include an output controller 1234, such as a serial (e.g., universal serial bus (USB), parallel, or other wired or wireless (e.g., infrared (IR), near field communication (NFC), etc.) connection to communicate with or control one or more peripheral devices (e.g., a printer, a card reader, etc.)).

The storage device 1216 may include a machine readable medium 1222 on which is stored one or more sets of data structures or instructions 1224 (e.g., software) embodying or utilized by any one or more of the techniques or functions described herein. The instructions 1224 may also reside, completely or at least partially, within the main memory 1204, within the static memory 1206, or within the hardware processor 1202 during execution thereof by the computing device 1200. In an example, one or any combination of the hardware processor 1202, the main memory 1204, the static memory 1206, or the storage device 1216 may constitute machine-readable media.

While the machine-readable medium 1222 is illustrated as a single medium, the term “machine-readable medium” may include a single medium or multiple media (e.g., a centralized or distributed database, and/or associated caches and servers) configured to store the one or more instructions 1224.

Various embodiments may be implemented fully or partially in software and/or firmware. This software and/or firmware may take the form of instructions contained in or on a non-transitory computer-readable storage medium. Those instructions may then be read and executed by one or more processors to enable performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read only memory (ROM); random access memory (RAM); magnetic disk storage media; optical storage media; a flash memory, etc.

The term “machine-readable medium” may include any medium that is capable of storing, encoding, or carrying instructions for execution by the computing device 1200 and that cause the computing device 1200 to perform any one or more of the techniques of the present disclosure, or that is capable of storing, encoding, or carrying data structures used by or associated with such instructions. Non-limiting machine-readable medium examples may include solid-state memories and optical and magnetic media. In an example, a massed machine-readable medium includes a machine-readable medium with a plurality of particles having resting mass. Specific examples of massed machine-readable media may include non-volatile memory, such as semiconductor memory devices (e.g., electrically programmable read-only memory (EPROM), or electrically erasable programmable read-only memory (EEPROM)) and flash memory devices; magnetic disks, such as internal hard disks and removable disks; magneto-optical disks; and CD-ROM and DVD-ROM disks.

The instructions 1224 may further be transmitted or received over a communications network 1226 using a transmission medium via the network interface device/transceiver 1220 utilizing any one of a number of transfer protocols (e.g., frame relay, internet protocol (IP), transmission control protocol (TCP), user datagram protocol (UDP), hypertext transfer protocol (HTTP), etc.). Example communications networks may include a local area network (LAN), a wide area network (WAN), a packet data network (e.g., the Internet), mobile telephone networks (e.g., cellular networks), plain old telephone (POTS) networks, wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, and peer-to-peer (P2P) networks, among others. In an example, the network interface device/transceiver 1220 may include one or more physical jacks (e.g., Ethernet, coaxial, or phone jacks) or one or more antennas to connect to the communications network 1226. In an example, the network interface device/transceiver 1220 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the computing device 1200 and includes digital or analog communications signals or other intangible media to facilitate communication of such software. The operations and processes described and shown above may be carried out or performed in any suitable order as desired in various implementations. Additionally, in certain implementations, at least a portion of the operations may be carried out in parallel. Furthermore, in certain implementations, less than or more than the operations described may be performed.

Some embodiments may be used in conjunction with various devices and systems, for example, a personal computer (PC), a desktop computer, a mobile computer, a laptop computer, a notebook computer, a tablet computer, a server computer, a handheld computer, a handheld device, a personal digital assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless access point (AP), a wired or wireless router, a wired or wireless modem, a video device, an audio device, an audio-video (A/V) device, a wired or wireless network, a wireless area network, a wireless video area network (WVAN), a local area network (LAN), a wireless LAN (WLAN), a personal area network (PAN), a wireless PAN (WPAN), and the like.

Some embodiments may be used in conjunction with one way and/or two-way radio communication systems, cellular radio-telephone communication systems, a mobile phone, a cellular telephone, a wireless telephone, a personal communication system (PCS) device, a PDA device which incorporates a wireless communication device, a mobile or portable global positioning system (GPS) device, a device which incorporates a GPS receiver or transceiver or chip, a device which incorporates an RFID element or chip, a multiple input multiple output (MIMO) transceiver or device, a single input multiple output (SIMO) transceiver or device, a multiple input single output (MISO) transceiver or device, a device having one or more internal antennas and/or external antennas, digital video broadcast (DVB) devices or systems, multi-standard radio devices or systems, a wired or wireless handheld device, e.g., a smartphone, a wireless application protocol (WAP) device, or the like.

Some embodiments may be used in conjunction with one or more types of wireless communication signals and/or systems following one or more wireless communication protocols, for example, radio frequency (RF), infrared (IR), frequency-division multiplexing (FDM), orthogonal FDM (OFDM), time-division multiplexing (TDM), time-division multiple access (TDMA), extended TDMA (E-TDMA), general packet radio service (GPRS), extended GPRS, code-division multiple access (CDMA), wideband CDMA (WCDMA), CDMA 2000, single-carrier CDMA, multi-carrier CDMA, multi-carrier modulation (MDM), discrete multi-tone (DMT), Bluetooth®, global positioning system (GPS), Wi-Fi, Wi-Max, ZigBee, ultra-wideband (UWB), global system for mobile communications (GSM), 2G, 2.5G, 3G, 3.5G, 4G, fifth generation (5G) mobile networks, 3GPP, long term evolution (LTE), LTE advanced, enhanced data rates for GSM Evolution (EDGE), or the like. Other embodiments may be used in various other devices, systems, and/or networks.

Further, in the present specification and annexed drawings, terms such as “store,” “storage,” “data store,” “data storage,” “memory,” “repository,” and substantially any other information storage component relevant to the operation and functionality of a component of the disclosure, refer to memory components, entities embodied in one or several memory devices, or components forming a memory device. It is noted that the memory components or memory devices described herein embody or include non-transitory computer storage media that can be readable or otherwise accessible by a computing device. Such media can be implemented in any methods or technology for storage of information, such as machine-accessible instructions (e.g., computer-readable instructions), information structures, program modules, or other information objects.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language generally is not intended to imply that features, elements, and/or operations are in any way required for one or more implementations or that one or more implementations necessarily include logic for deciding, with or without user input or prompting, whether these features, elements, and/or operations are included or are to be performed in any particular implementation.

What has been described herein in the present specification and annexed drawings includes examples of systems, devices, techniques, and computer program products that, individually and in combination, certain systems and methods. It is, of course, not possible to describe every conceivable combination of components and/or methods for purposes of describing the various elements of the disclosure, but it can be recognized that many further combinations and permutations of the disclosed elements are possible. Accordingly, it may be apparent that various modifications can be made to the disclosure without departing from the scope or spirit thereof. In addition, or as an alternative, other embodiments of the disclosure may be apparent from consideration of the specification and annexed drawings, and practice of the disclosure as presented herein. It is intended that the examples put forth in the specification and annexed drawings be considered, in all respects, as illustrative and not limiting. Although specific terms are employed herein, they are used in a generic and descriptive sense only and not for purposes of limitation.

What is claimed is:

1. A method comprising:
determining, using one or more processors, one or more first electrical fields associated with operation of an electrical component;
comparing, using the one or more processors, the one or more first electrical fields with a second electrical field associated with partial discharge (PD) inception in the electrical component;
determining, using the one or more processors, that a first value associated with the one or more first electric fields is less than or equal to a second value associated with the second electric field; and
generating, using the one or more processors and based on the determination that the first value is less than or equal to the second value, parameters for insulation of the electrical component.

2. The method of claim 1, further comprising:
causing, using the one or more processors, the insulation to be created based on the parameters.

3. The method of claim 1, further comprising:
causing, using the one or more processors, an existing insulation to be modified based on the parameters.

4. The method of claim 1, wherein the one or more first electric fields include at least one of:
a maximum orthogonal electric field and a maximum tangential electrical field of the electrical component at an operating temperature of the electrical component.

5. The method of claim 1, further comprising:
determining a PD measurement associated with the electrical component; and
comparing at least one of the first value and the second value to the PD measurement.

6. The method of claim 1, wherein the determining the one of more first electrical fields is performed at a maximum operating voltage of the electrical component.

7. The method of claim 1, wherein the electrical component includes at least one of a spacer, a bushing, a power electronic board, a printed circuit board (PCB), and/or a laminated bushbar (LBB).

8. A system comprising:
one or more processors; and
a memory storing computer-executable instructions, that when executed by the one or more processors, cause the one or more processors to:
determine one or more first electrical fields associated with operation of an electrical component;
compare the one or more first electrical fields with a second electrical field associated with partial discharge (PD) inception in the electrical component;
determine that a first value associated with the one or more first electric fields is less than or equal to a second value associated with the second electric field; and
generate, based on the determination that the first value is less than or equal to the second value, parameters for insulation of the electrical component.

9. The system of claim 8, wherein the computer-executable instructions further cause the one or more processors to:
cause the insulation to be created based on the parameters.

10. The system of claim 8, wherein the computer-executable instructions further cause the one or more processors to:
cause an existing insulation to be modified based on the parameters.

11. The system of claim 8, wherein the one or more first electric fields include at least one of: a maximum orthogonal electric field and a maximum tangential electrical field of the electrical component at an operating temperature of the electrical component.

12. The system of claim 8, wherein the computer-executable instructions further cause the one or more processors to:
determine a PD measurement associated with the electrical component; and
compare at least one of the first value and the second value to the PD measurement.

13. The system of claim 8, wherein determining the one of more first electrical fields is performed at a maximum operating voltage of the electrical component.

14. The system of claim 8, wherein the electrical component includes at least one of a spacer, a bushing, a power electronic board, a printed circuit board (PCB), and/or a laminated bushbar (LBB).

15. A non-transitory computer readable medium including computer-executable instructions stored thereon, which when executed by one or more processors, cause the one or more processors to perform operations of:
determining one or more first electrical fields associated with operation of an electrical component;
comparing the one or more first electrical fields with a second electrical field associated with partial discharge (PD) inception in the electrical component;
determining that a first value associated with the one or more first electric fields is less than or equal to a second value associated with the second electric field; and
generating, based on the determination that the first value is less than or equal to the second value, parameters for insulation of the electrical component.

16. The non-transitory computer readable medium of claim 15, wherein the computer-executable instructions further cause the one or more processors to perform operations of:
causing, using the one or more processors, the insulation to be created based on the parameters.

17. The non-transitory computer readable medium of claim 15, wherein the one or more first electric fields include at least one of: a maximum orthogonal electric field and a maximum tangential electrical field of the electrical component at an operating temperature of the electrical component.

18. The non-transitory computer readable medium of claim 15, wherein the computer-executable instructions further cause the one or more processors to perform operations of:
determining a PD measurement associated with the electrical component; and
comparing at least one of the first value and the second value to the PD measurement.

19. The non-transitory computer readable medium of claim 15, wherein the determining the one of more first electrical fields is performed at a maximum operating voltage of the electrical component.

20. The non-transitory computer readable medium of claim 15, wherein the electrical component includes at least one of a spacer, a bushing, a power electronic board, a printed circuit board (PCB), and/or a laminated bushbar (LBB).
